(19) United States
(12) Patent Application Publication
(10) Pub. No.: US 2009/0020423 A1
(43) Pub. Date: Jan. 22, 2009

(54) Potentiometric Mg2+ Sensor and Method thereof

(75) Inventors: Shen-Kan Hsiung, Tao-Yuan (TW); Jung-Chuan Chou, Tao-Yuan (TW); Tai-Ping Sun, Tao-Yuan (TW); Nien-Hsuan Chou, Tao-Yuan (TW); Wei-Feng Liang, Tao-Yuan (TW)

Correspondence Address: WPAT, PC, 7225 BEVERLY ST., ANNANDALE, VA, 22003, US

(73) Assignee: CHUNG YUAN CHRISTIAN UNIVERSITY, Tao-Yuan (TW)

(21) Appl. No.: 11/778,676

(22) Filed: Jul. 17, 2007

(51) Int. Cl. G01N 27/414; C23C 14/34

(52) U.S. Cl. 204/415; 204/192.1

(57) ABSTRACT

A potentiometric Mg²⁺ sensor is disclosed, wherein the potentiometric SnO₂/ITO-based Mg²⁺ ISE was developed in this invention. The magnesium ion-selective membrane was fabricated and dripped on the surface of SnO₂. The performance, such as sensitivity, was exhibited by the magnesium ion-selective membrane having magnesium ionophore, K-TpClPB, plasticizer, PVC in the suitable ratios. Moreover, the Mg²⁺ ISE was measured in different Mg²⁺ concentration buffer solutions. According to the experimental results, the best sensitivity of the Mg²⁺ sensor is 31.7l mV/decade between 10-4M and 10-1M, and measurement time is 30 sec.

### BACKGROUND OF THE INVENTION

1. Field of the Invention

The present invention generally relates to magnesium ion sensor and fabrication method, and more particularly to potentiometric magnesium ion sensor and fabrication method.

2. Description of the Prior Art

For hygiene, the concentration of Mg2+ is one of the most important parameter in the clinical assay, the Mg2+ activity in blood serum was shown to decrease during liver transplantation due to accumulation of citrate and concomitant chelation of Mg2+. A low Mg2+ activity has been observed in patients suffering from acute migraine, headaches and cardiac diseases. The disadvantage of traditional potentiometric Mg²⁺ devices are expensive and hard to fabricate. In order to make the measurement of magnesium ion easily, magnesium ISEs (Ion-selective electrode) have been developed in this invention.

### SUMMARY OF THE INVENTION

Therefore, in accordance with the previous summary, objects, features and advantages of the present disclosure will become apparent to one skilled in the art from the subsequent description and the appended claims taken in conjunction with the accompanying drawings.

A potentiometric magnesium ion sensor and fabrication method is disclosed. At first, a conduction layer is formed on a substrate. Then, a SnO₂ thin-film is deposited on the conduction layer by radio frequency sputtering method, and the conduction layer, the SnO₂ thin-film and a conducting line are connected by a conduction paste. Thereupon, an insulation layer is formed, wherein the conduction layer, the SnO₂ thin-film and one end of the conducting line are coated with the insulation layer, and an opening of the insulation layer is formed on the SnO₂ thin-film. Finally, a magnesium ion-selective membrane is formed by dropping the material of the magnesium ion-selective membrane on the opening.

### BRIEF DESCRIPTION OF THE DRAWINGS

The accompanying drawings incorporated in and forming a part of the specification illustrate several aspects of the present invention, and together with the description serve to explain the principles of the disclosure. In the drawings:

FIG. 1 is a diagram illustrates the fabrication and structural diagram of a potentiometric magnesium ion sensor;

FIG. 2 is a diagram depicts the operations of a potentiometric magnesium ion system; and

FIG. 3, FIG. 4, FIG. 5 and FIG. 6 are diagrams show the experimental data.

### DETAILED DESCRIPTION OF THE PREFERRED EMBODIMENTS

The present disclosure can be described by the embodiments given below. It is understood, however, that the embodiments below are not necessarily limitations to the present disclosure, but are used to a typical implementation of the invention.

Having summarized various aspects of the present invention, reference will now be made in detail to the description of the invention as illustrated in the drawings. While the invention will be described in connection with these drawings, there is no intent to limit it to the embodiment or embodiments disclosed therein. On the contrary the intent is to cover all alternatives, modifications and equivalents included within the spirit and scope of the invention as defined by the appended claims.

It is noted that the drawings presents herein have been provided to illustrate certain features and aspects of embodiments of the invention. It will be appreciated from the description provided herein that a variety of alternative embodiments and implementations may be realized, consistent with the scope and spirit of the present invention.

It is also noted that the drawings presents herein are not consistent with the same scale. Some scales of some components are not proportional to the scales of other components in order to provide comprehensive descriptions and emphasizes to this present invention.

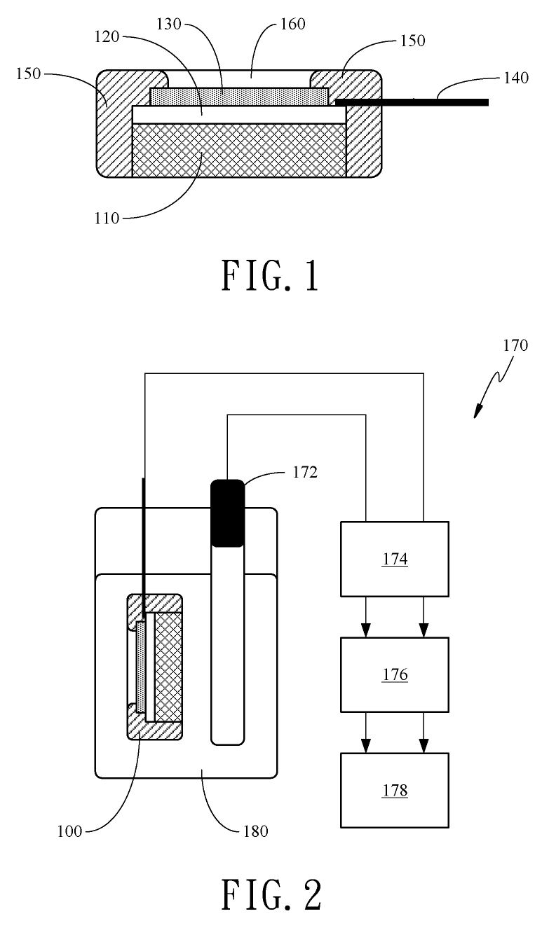

Please refer to FIG. 1, which is a fabrication and structural diagram of a potentiometric magnesium ion sensor 100. At first, a conduction layer 120 is formed on a substrate 110. Then, a SnO₂ thin-film 130 is deposited on the conduction layer 120 by radio frequency sputtering method, and the conduction layer 120, the SnO₂ thin-film 130 and a conducting line 140 are connected by a conduction paste. Thereupon, an insulation layer 150 is formed, wherein the conduction layer 120, the SnO₂ thin-film 130 and one end of the conducting line 140 are coated with the insulation layer 150, and an opening of the insulation layer 150 is formed on the SnO₂ thin-film 130. Finally, a magnesium ion-selective membrane 160 is formed by dropping the material of the magnesium ion-selective membrane 160 on the opening.

The substrate 110 could comprise glass, and the conduction layer 120 could comprise Indium Tin Oxide (ITO). The insulation layer 150 could comprise Epoxy, and the conduction paste could comprise silver paste. The magnesium ion-selective membrane 160 consists of magnesium ionophore, K-TpClPB, plasticizer, and Poly (vinyl choride). Moreover, the performance was exhibited by the magnesium ion-selective membrane having magnesium ionophore:K-TpClPB: plasticizer:Poly(vinyl choride) in the weight ratio (wt %) 1.40:1.00:64.50:33.10.

However, the FIG. 1 also shows the structure of the potentiometric magnesium ion sensor 100, comprising the substrate 110, the conduction layer 120, the SnO₂ thin-film 130, the conducting line 140, the insulation layer 150 and the magnesium ion-selective membrane 160. The conduction layer 120 is formed on the substrate 110, and the SnO₂ thin-film 130 is formed on the conduction layer 120. The conduction layer 120 and the SnO₂ thin-film 130 is coated with the insulation layer 150, and an opening of the insulation layer 150 is formed above the SnO₂ thin-film 130. The magnesium ion-selective membrane 160 is formed on the opening, wherein the magnesium ion-selective membrane 160 is for magnesium ions passing, and redox reaction would be made between magnesium ions and the SnO₂ thin-film 130.

Also as noted above, the potentiometric magnesium ion sensor 100 further includes the above-mentioned conducting line 140, wherein one end of the conducting line 140 is connected to the conduction layer 120 and the SnO₂ thin-film 130, and the conduction layer 120, the SnO₂ thin-film 130 and the conducting line 140 could by the conduction paste, which could be silver paste.

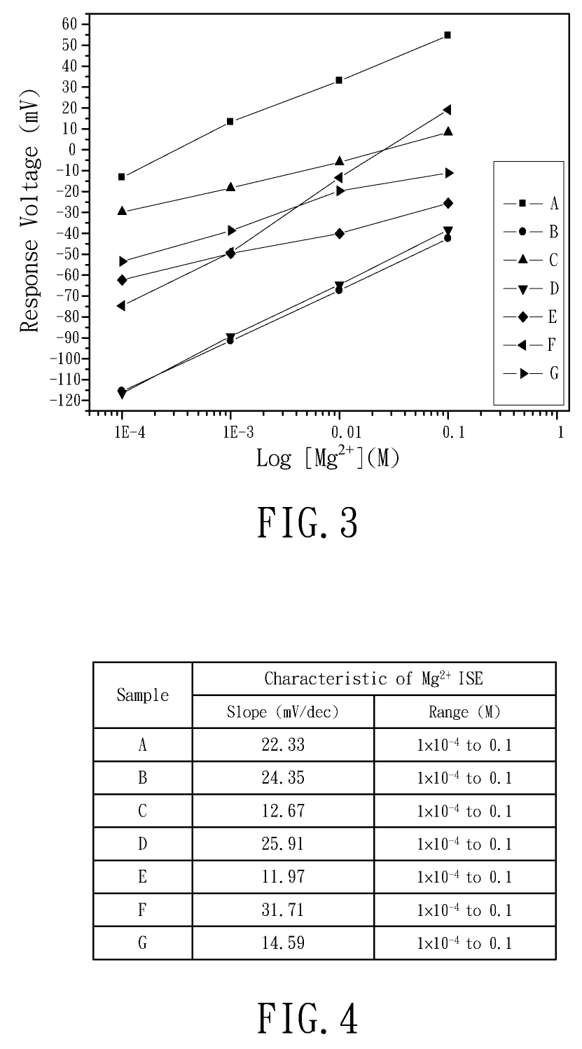

The potentiometric magnesium ion system 170 is shown in FIG. 2. As shown in the FIG. 2, the potentiometric magnesium ion system 170 comprises the potentiometric magnesium ion sensor 100, a reference electrode 172, an amplifier (LT1167) 174, a digital multi-meter 176, and a computer 178.

The amplifier is electronically coupled with the conduction layer 120 by the conducting line 140, wherein one end of the conducting line 140 is connected to the conduction layer 120 and the SnO₂ thin-film 130, and the other end of the conducting line 140 is connected with the amplifier 174 by passing through the insulation layer 150. Moreover, the digital multi-meter 176 is electronically coupled with the amplifier 174, and measures the output signals from the amplifier 174 to output measurement values. Then, the computer 178 is electronically coupled with the digital multi-meter 176 for computing the measurement values from the digital multi-meter 176.

The potentiometric magnesium ion sensor 100 and the reference electrode 172 are immersed into a butter solution 180, and the reference electrode 172 is held out at a reference potential. When magnesium ions pass through the magnesium ion-selective membrane 160 to react with the SnO₂ thin-film 130, the potentiometric magnesium ion sensor 100 would output a signal according to a potential difference between the potentiometric magnesium ion sensor 100 and the reference electrode 172.

The signal from the potentiometric magnesium ion sensor 100 is immediately transmitted to the digital multi-meter 176 and the computer 178 by the amplifier 174, and the concentration of the magnesium ions in the buffer solution 180 is measured and analyzed by the digital multi-meter 176 and the computer 178.

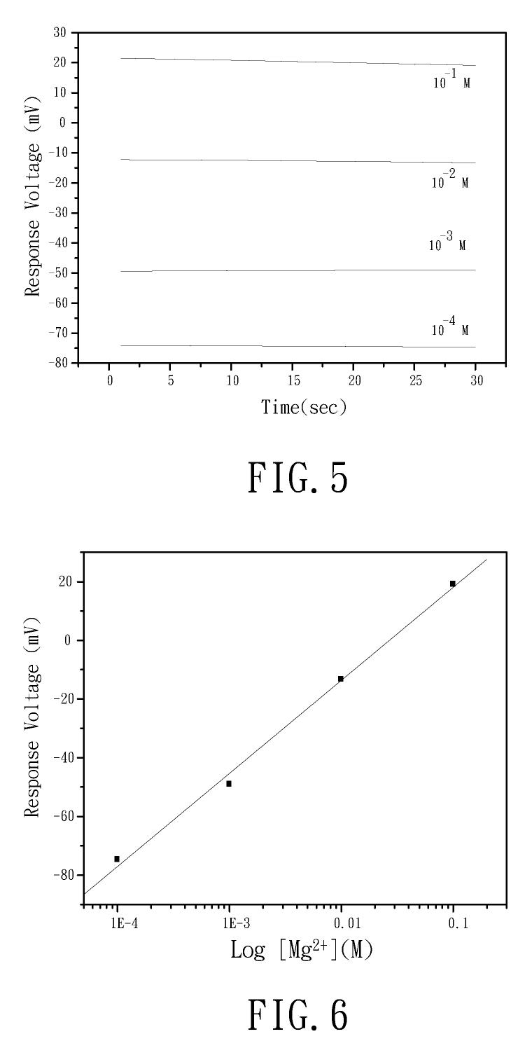

According to the experimental results, the sensitivity of the potentiometric magnesium ion sensor 100 is about 31.71 mV/decade when the concentration range of the magnesium ions is between 1×10-4 M and 0.1 M, and measurement time is about 30 seconds. Besides, the relations between the concentration of the magnesium ions and the potential are shown in FIG. 3 and FIG. 4, and the reaction curve of the potentiometric magnesium ion sensor 100 is shown in FIG. 5, wherein the reaction time is less than 1 second. In addition, the best sensitivity of the potentiometric magnesium ion sensor 100 is about 31.71 mV/decade when the concentration range of the magnesium ions in the buffer solution 180 is between 1×10-4 M and 0.1 M, as shown in FIG. 6.

The foregoing description is not intended to be exhaustive or to limit the invention to the precise forms disclosed. Obvious modifications or variations are possible in light of the above teachings. In this regard, the embodiment or embodiments discussed were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the inventions as determined by the appended claims when interpreted in accordance with the breath to which they are fairly and legally entitled.

It is understood that several modifications, changes, and substitutions are intended in the foregoing disclosure and in some instances some features of the invention will be employed without a corresponding use of other features. Accordingly, it is appropriate that the appended claims be construed broadly and in a manner consistent with the scope of the invention.

1. A potentiometric magnesium ion sensor, comprising:
a substrate;
a conduction layer, deposited on said substrate;
a SnO₂ thin-film, deposited on said conduction layer;
an insulation layer, wherein said conductive layer and said SnO₂ thin-film is coated with said insulation layer, and an opening of said insulation layer is formed on the SnO₂ thin-film; and
a magnesium ion selective membrane, formed at said opening, wherein said magnesium ion selective membrane is only for magnesium ion to pass through.

2. A potentiometric magnesium ion sensor of claim 1, wherein said magnesium ion-selective membrane includes magnesium ionophore, K-TpClPB, plasticizer, and PVC (Polyvinyl chloride polymer).

3. A potentiometric magnesium ion sensor of claim 2, wherein said magnesium ion-selective membrane includes magnesium ionophore:K-TpClPB:plasticizer:Poly (vinyl choride) in the weight ratio (wt %) 1.40:1.00:64.50:33.10.

4. A potentiometric magnesium ion sensor of claim 1, wherein said substrate includes glass.

5. A potentiometric magnesium ion sensor of claim 1, wherein said conduction layer includes ITO (Indium Tin Oxide).

6. A potentiometric magnesium ion sensor of claim 1, wherein said insulation layer includes Epoxy.

7. A potentiometric magnesium ion sensor of claim 1, further comprising a conducting line, wherein one side of the conducting line has coupling with said conduction layer and said SnO₂ thin-film.

8. A potentiometric magnesium ion sensor of claim 7, wherein said conduction layer, said SnO₂ thin-film and said conducting line are connecte by a electric conduction paste.

9. A potentiometric magnesium ion sensor of claim 8, wherein said electric conduction paste includes silver paste.

10. A potentiometric magnesium ion system, comprising:
a reference electrode which was held out at a reference potential;
a potentiometric magnesium ion sensor, comprising:
a substrate;
a conduction layer, deposited on said substrate;
a SnO₂ thin-film, deposited on said conduction layer;
an insulation layer, wherein coating said conductive layer and said SnO₂ thin-film is coated with said insulation layer, and an opening of said insulation layer is formed on the SnO₂ thin-film; and
a magnesium ion-selective membrane, formed at said opening, wherein said magnesium ion-selective membrane is only for magnesium ion to pass through; and
a amplifier, coupled with said conduction layer by a conducting line, wherein one side of the conducting line has coupling with the conduction layer and SnO₂ thin-film, and another side of the conducting line has coupling with the amplifier passed insulation layer.

11. A potentiometric magnesium ion system of claim 10, further comprising a digital multi-meter which has coupling with the amplifier, and measures the output signals from said amplifier to output measurement values.

12. A potentiometric magnesium ion system of claim 11, further comprising a computer which has coupling with the digital multi-meter, and computes the output signals from said digital multi-meter.

13. A potentiometric magnesium ion system of claim 10, wherein said magnesium ion-selective membrane includes magnesium ionophore, K-TpClPB, plasticizer, Poly (vinyl choride).

14. A potentiometric magnesium ion system of claim 13, wherein said magnesium ion-selective membrane includes magnesium ionophore:K-TpClPB:plasticizer:Poly (vinyl choride) in the weight ratio (wt %) 1.40:1.00:64.50:33.10.

15. A potentiometric magnesium ion system of claim 10, wherein said substrate includes glass.

16. A potentiometric magnesium ion system of claim 10, wherein said conduction layer includes Indium Tin Oxide.

17. A potentiometric magnesium ion system of claim 10, wherein said insulation layer includes Epoxy.

18. A potentiometric magnesium ion system of claim 10, wherein said conduction layer, said SnO₂ thin-film and said conducting line are connected by a electric conduction paste.

19. A potentiometric magnesium ion system of claim 18, wherein said electric conduction paste includes silver paste.

20. A potentiometric magnesium ion system of claim 10, further comprising a butter solution, wherein said reference electrode and said potentiometric magnesium ion sensor are immersed in said butter solution.

21. A potentiometric magnesium ion fabrication method, comprising the steps of:
providing a substrate;
forming an conduction layer on said substrate;
depositing a SnO₂ thin-film on said conduction layer by radio frequency sputtering method;
connecting said conduction layer and said SnO₂ thin-film with a conducting line by a conduction paste;
forming an insulation layer, wherein said conduction layer, said SnO₂ thin-film and one end of said conducting line are coated with said insulation layer, and an opening of said insulation layer is formed on the SnO₂ thin-film; and
dropping the material of a magnesium ion-selective membrane on said opening to form said magnesium ion-selective membrane.

22. A potentiometric magnesium ion fabrication method of claim 21, wherein said magnesium ion-selective membrane includes magnesium ionophore, K-TpClPB, plasticizer, Poly (vinyl choride).

23. A potentiometric magnesium ion fabrication method of claim 21, wherein said magnesium ion-selective membrane includes magnesium ionophore:K-TpClPB:plasticizer:Poly (vinyl choride) in the weight ratio (wt %) 1.40:1.00:64.50:33.10.

24. A potentiometric magnesium ion fabrication method of claim 21, wherein said substrate includes glass.

25. A potentiometric magnesium ion fabrication method of claim 21, wherein said conduction layer includes Indium Tin Oxide.

26. A potentiometric magnesium ion fabrication method of claim 21, wherein said insulation layer includes Epoxy.

27. A potentiometric magnesium ion fabrication method of claim 21, wherein said electric conduction paste includes silver paste.
